(19) United States
(12) Patent Application Publication
(10) Pub. No.: US 2003/0008515 A1
(43) Pub. Date: Jan. 9, 2003

(54) Method of fabricating a vertical MOS transistor

(76) Inventors: Tai-Ju Chen, Tai-Nan City (TW); Hua-Chou Tseng, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 09/681,988

(22) Filed: Jul. 3, 2001

(51) Int. Cl. H01L 21/311

(52) U.S. Cl. 438/700

(57) ABSTRACT

A gate mask is formed on a silicon substrate of a semiconductor wafer followed by etching region of the silicon substrate not covered by the gate mask to a predetermined depth. Subsequently, a silicon oxide layer is formed on the region of the silicon substrate not covered by the gate mask. A first conductive layer and a second conductive layer are formed respectively on the silicon substrate. Then, a first etching back process is performed to form a spacer consisting of the second conductive layer, the first conductive layer and the silicon oxide layer on the region of the silicon substrate below the gate mask. After the gate mask is removed, a selective etching process is performed to remove portions of both the first conductive layer and the silicon oxide layer to form the spacer into an undercut profile. Finally, a doping process and an ion implantation process are performed, respectively, to form lightly doped drains (LDDs) and a source/drain (S/D) of a vertical MOS transistor.

### BACKGROUND OF INVENTION

1. Field of the Invention

The present invention relates to a method of fabricating a vertical metal-oxide semiconductor (MOS) transistor, and more particularly, to a method of fabricating a vertical MOS transistor with lightly doped drains (LDDs).

2. Description of the Prior Art

With the development of very large scale integration (VLSI), low electricity consumption and high integration of MOS transistors allows them to be widely applied in the semiconductor process. Usually, a MOS transistor comprises a gate and two semiconductor regions, called a source and drain located on each side of a capacitor with an electrical characteristic opposite to that of the silicon substrate. The major structure of the gate is composed of a gate oxide layer and a gate conductive layer. When a proper bias is added to the gate, the MOS transistor can be regarded as a solid switch to control the connection of current.

In typical MOS transistors, the source, gate and drain are arranged in a common horizontal plane. A critical dimension in the fabrication of the horizontal MOS transistors is the length of the channel, which is defined as a distance between the source and the drain. The length of the channel not only affects the number of transistors that can be provided in a given space, but impacts transistor operation. Therefore, it is limited to minimize the channel size of the horizontal MOS transistors to increase the integration of the semiconductor devices. A vertical MOS transistor includes the source, gate and drain arranged in a vertical direction, thus having a vertical channel to effectively reduce a lateral area of the MOS transistor and increase the integration of the semiconductor devices.

Please refer to FIG. 1 to FIG. 7 of schematic diagrams of a prior art method of fabricating a vertical MOS transistor. As shown in FIG. 1, a sacrificial layer 14, such as a silicon oxide layer, is formed on a silicon substrate 12 of a semiconductor wafer 10. The sacrificial layer 14 covers portions of the silicon substrate 12 and has at least a vertical side wall 14a positioned in an active area, functioning to define the position for forming a gate of the vertical MOS transistor. Subsequently, a chemical vapor deposition (CVD) process is performed to form another sacrificial layer 16 on the surfaces of both the sacrificial layer 14 and the silicon substrate 12. For example, the sacrificial layer 16 is made of silicon nitride.

Following this, as shown in FIG. 2, an etching back process is performed to remove portions of the sacrificial layer 16, forming a spacer as a gate mask 17 on the surface of the vertical side wall 14a of the sacrificial layer 14. Then, a dry etching process is performed to completely remove the sacrificial layer 14. As shown in FIG. 3, a dry etching process is again used, to remove a region of the silicon substrate 12 not covered by the gate mask 17 down to a predetermined depth. The predetermined depth is generally hundreds to thousands of angstroms (Å). As a result, a trench 18 is formed in the region of the silicon substrate 12 at two sides of the gate mask 17. A depth L₁ of the trench 18 approximately defines a channel length of the vertical MOS transistor.

As shown in FIG. 4, the semiconductor wafer 10 is placed in a furnace, followed by injecting oxygen into at atmospheric pressure. Thus, by using dry oxidation or wet oxidation, the single crystal silicon on the surface of the silicon substrate 12 is oxidized to grow a silicon oxide layer 20. Subsequently, a conductive layer 22 is deposited on the surface of the semiconductor wafer 10. The conductive layer 22 is made of doped polysilicon. Alternatively, an undoped polysilicon layer may be used to replace the conductive layer 22.

As shown in FIG. 5, an etching back process is thereafter performed to anisotropically remove the conductive layer 22, thereby forming a spacer functioning as a gate conductive layer 23 on the region of the silicon substrate 12 below the gate mask 17. After the gate conductive layer 23 is formed, adjusting an etching selectivity of the silicon oxide layer 20 to polysilicon and using the gate conductive layer 23 as an etching mask, portions of the silicon oxide layer 20 outside the gate conductive layer 23 are removed, thus forming a gate oxide layer 21 by the remainder of the silicon oxide layer 20.

As shown in FIG. 6, the gate mask 17, made of silicon nitride, is then removed using a wet etching with heated phosphoric acid. Finally, as shown in FIG. 7, an ion implantation process is performed to form a doped region on top of the silicon substrate 12 between the two gate conductive layers 23, and on regions of the silicon substrate 12 outside the two gate conductive layers 23. The doped region on the top of the silicon substrate 12 between the two gate conductive layers 23 functions as a drain 24 of the vertical MOS transistor, and the doped regions on the regions of the silicon substrate 12 outside the two gate conductive layers 23 function as a source 26 of the vertical MOS transistor. In addition, during the ion implantation process, the gate conductive layer 23 made of undoped polysilicon is also implanted to become doped polysilicon.

Since the vertical MOS transistor of the prior art does not have the LDD structures, the voltage between the gate and drain is inevitably higher than that of a MOS transistor with structures. While the voltage between the gate and drain of the MOS transistor gets higher, the hot-carrier effect increases. As a result, substrate currents, oxide charging and characteristic variations on the oxide/silicon substrate interface occur to affect the quality of the MOS transistor.

### SUMMARY OF INVENTION

It is therefore an objective of the present invention to provide a method of fabricating a vertical MOS transistor with LDD structures to reduce the hot-carrier effect.

It is another objective of the present invention to provide a method of fabricating a vertical MOS transistor to prevent boron penetration.

According to the claimed invention, a gate mask is formed on a silicon substrate of a semiconductor wafer followed by etching a region of the silicon substrate not covered by the gate mask to a predetermined depth. Subsequently, a silicon oxide layer is formed on the region of the silicon substrate not covered by the gate mask. A first conductive layer and a second conductive layer are formed, in order, on the silicon substrate. Then, a first etching back process is performed to form a spacer consisting of the second conductive layer, the first conductive layer and the silicon oxide layer on the region of the silicon substrate below the gate mask. After the gate mask is removed, a selective etching process is performed to remove portions of both the first conductive layer and the silicon oxide layer to form the spacer into an undercut profile. Finally, a doping process and an ion implantation process are performed, respectively, to form LDDs and a source/drain (S/D) of the vertical MOS transistor.

It is an advantage of the present invention that the selective etching between the first conductive layer and the second conductive layer is utilized to form the undercut profile of the spacer and expose the regions of the silicon substrate for forming the LDDs. Following this, the doping process is used to form the LDDs on the silicon substrate, hence effectively reducing the voltage between the gate and drain and the hot-carrier effect of the MOS transistor.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 to FIG. 7 are schematic diagrams of a prior art method of fabricating a vertical MOS transistor.

FIG. 8 to FIG. 16 are schematic diagrams of a method of fabricating a vertical MOS transistor according to the present invention.

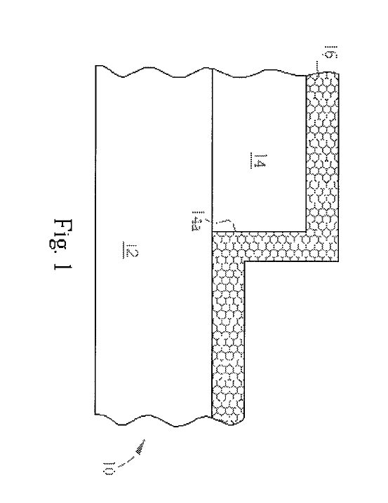

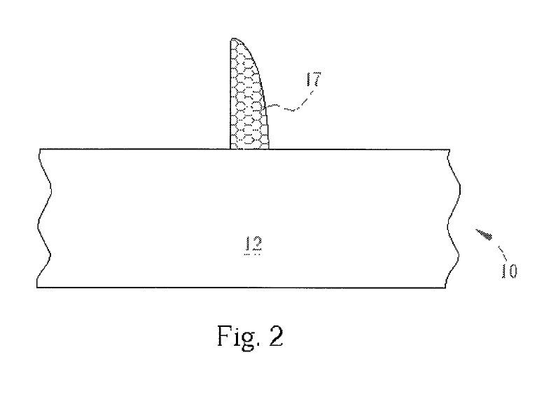

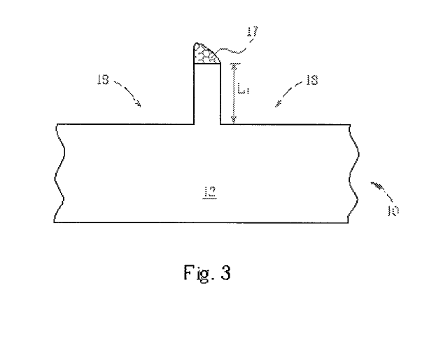

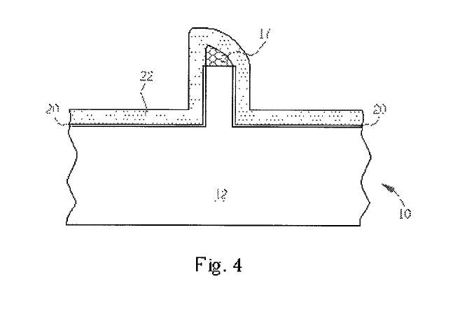

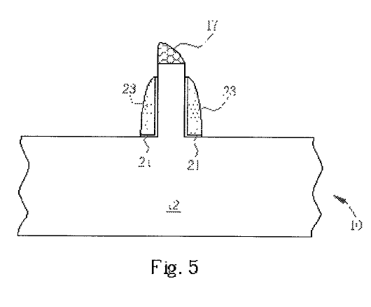

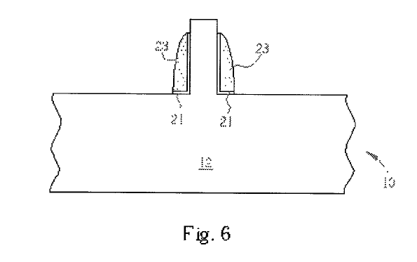

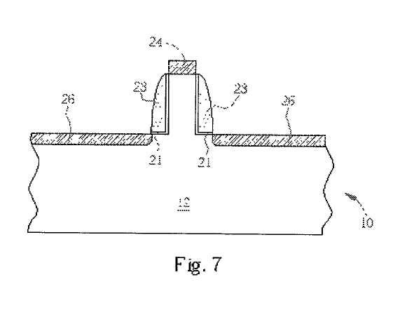

### DETAILED DESCRIPTION

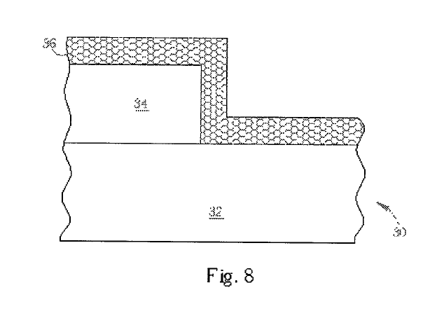

Please refer to FIG. 8 to FIG. 16 of schematic diagrams of a method of fabricating a vertical MOS transistor according to the present invention. As shown in FIG. 8, a sacrificial layer 34 is formed on a silicon substrate 32 of a semiconductor wafer 30. The sacrificial layer 34, made of silicon oxide compounds, covers portions of the silicon substrate 32. The sacrificial layer 34 has at least a vertical side wall 34a positioned in an active area to define the position for forming a gate of the vertical MOS transistor. Subsequently, a chemical vapor deposition is performed to form another sacrificial layer 36 on the surfaces of both the sacrificial layer 34 and the silicon substrate 32. The sacrificial layer 36 is made of silicon nitride compounds.

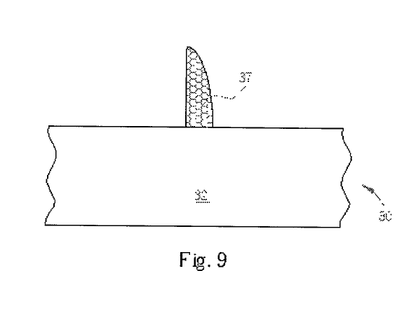

Following this, as shown in FIG. 9, an etching back process is performed to anisotropically remove portions of the sacrificial layer 36, as well as to form a spacer on the surface of the vertical side wall 34a of the sacrificial layer 34. The spacer functions as a gate mask 37. However, after the etching back process, the spacer is formed around the whole sacrificial layer 34. In order to define the position of the gate mask 37, a photoresist layer (not shown) can be formed to cover the position of the gate mask 37 followed by using an etching process to remove portions of the spacer that is unwanted. As a result, the position for forming a gate or a word line is defined surely. Following this, a dry etching process is performed to completely remove the sacrificial layer 34.

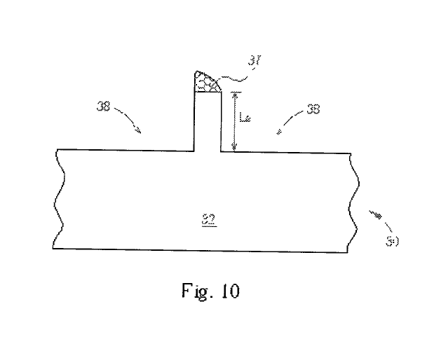

As shown in FIG. 10, a dry etching process is again used, to remove a region of the silicon substrate 32 not covered by the gate mask 37 down to a predetermined depth. The predetermined depth is generally hundreds to thousands of angstroms. As a result, a trench 38 is formed in the region of the silicon substrate 32 at two sides of the gate mask 37. The region of the silicon substrate 32 positioned between the two opposite trenches 38 functions as a vertical channel. A depth L₂ of the trench 38 approximately defines a channel length of the vertical MOS transistor. Selectively, an ion implantation process may be performed after the trench 38 is formed. The ion implantation is performed in an oblique direction to implant dopants into the region of the silicon substrate 32 between the two opposite trenches 38 below the gate mask 37, so as to adjust the threshold voltage of the vertical MOS transistor.

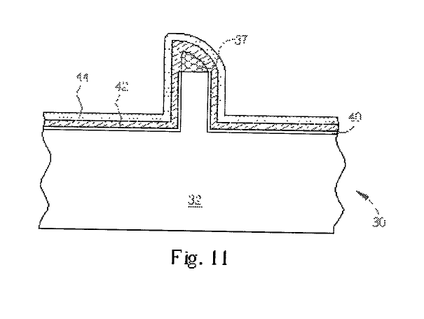

As shown in FIG. 11, the semiconductor wafer 30 is placed in a furnace, followed by injecting oxygen into the furnace at atmospheric pressure. Thus, using dry oxidation or wet oxidation, the surface of the silicon substrate 32 is oxidized to grow a silicon oxide layer 40. Subsequently, a conductive layer 42 and a conductive layer 44 are deposited, in order, on the surface of the semiconductor wafer 30. In a better embodiment of the present invention, the conductive layer 42 is made of poly silicon germanium (Si₁₋ₓGeₓ,x=0.05−1.0). The conductive layer 44 is made of poly silicon, including doped polysilicon or undoped polysilicon. Alternatively, the conductive layer 42 can also be made of amorphous silicon.

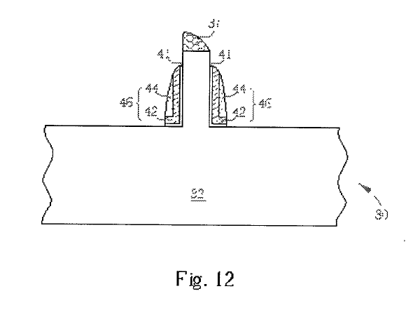

Subsequently, as shown in FIG. 12, an etching back process is performed to anisotropically remove portions of the conductive layer 44 and the conductive layer 42. As a result, a spacer consisting of the remaining conductive layers 44 and 42 positioned on the region of the silicon substrate 32 below the gate mask 37 is formed to function as a gate conductive layer 46. After the gate conductive layer 46 is formed, using the gate conductive layer 46 as an etching mask, an etching selectivity of the silicon oxide layer 40 to polysilicon is adjusted so as to selectively remove portions of the silicon oxide layer 40 outside the gate conductive layer 46. Hence, a gate oxide layer 41 is formed using the remainder of the silicon oxide layer 40.

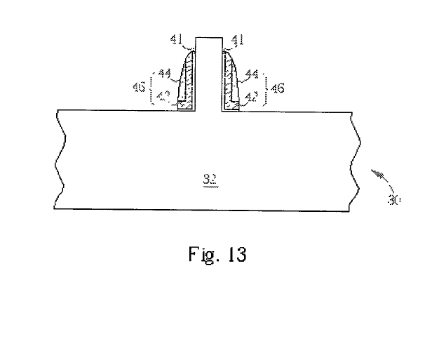

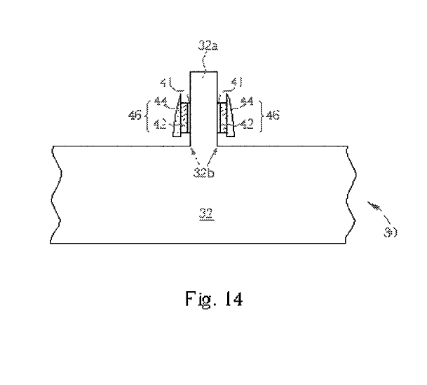

As shown in FIG. 13, the gate mask 37, made of silicon nitride compounds, is then removed using a wet etching with heated phosphoric acid. Following this, as shown in FIG. 14, a selective etching process is performed to remove portions of both the conductive layer 42 and the gate oxide layer 41, as well as to form the gate conductive layer 46 into an undercut profile. Specifically, after the selective etching process, the conductive layer 44 is longer than both the conductive layer 42 and the gate oxide layer 41. Additionally, after the selective etching process, the top 32a and the bottom 32b of the silicon substrate 32 that is adjacent to the gate oxide layer 41 are exposed for forming LDDs.

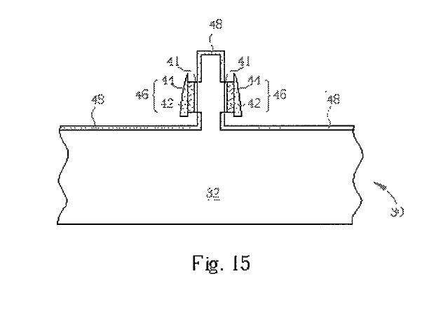

As shown in FIG. 15, a lightly doping process, such as a plasma doping process, is performed to form a doped region on the silicon substrate 32, the doped region functioning as an LDD 48. For forming the LDD 48, an ion implantation process is not used, such that dopants are prevented from implanting into the channel of the vertical MOS transistor.

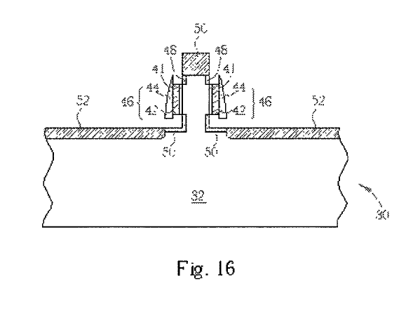

Following this, as shown in FIG. 16, a heavily doping process, such as an ion implantation process, is performed to form a doped region on top of the silicon substrate 32 between the two gate conductive layers 46, and form a doped region on regions of the silicon substrate 32 outside the two gate conductive layers 46. The doped region positioned on the top of the silicon substrate 32 between the two gate conductive layers 46 functions as a drain 50 of the vertical MOS transistor, and the doped regions positioned on the regions of the silicon substrate 32 outside the two gate conductive layers 46 function as a source 52 of the vertical MOS transistor. In addition, during the heavily doping process, dopants are also implanted into the gate conductive layer 46 to adjust the conductance of the gate conductive layer 46. Thus, fabrication of the vertical MOS transistor of the present invention is completed.

The vertical MOS transistor of the present invention may also be applied in a PMOS of a complementary metal-oxide semiconductor (CMOS) transistor. While in this application, the conductive layer 42 made of poly silicon germanium or amorphous silicon may function as a barrier layer between the conductive layer 44 and the gate oxide layer 41. Using this barrier layer, boron ions doping in the conductive layer 44 are prevented from penetrating through the gate oxide layer 41 and getting into the silicon substrate 32. As a result, problems resulting from boron penetration are prevented. Also, a stable threshold voltage of the MOS transistor is achieved to reduce leakage currents.

In contrast to the prior art of forming the vertical MOS transistor, the present invention uses a plurality of conductive layers to form the composite gate conductive layer. Following this, the selective etching between the different conductive layers is utilized so as to form the undercut profile of the gate conductive layer and expose the regions of the silicon substrate for forming the LDDs. Thereafter, the plasma doping is used to form the LDDs on the silicon substrate. Having the LDDs, both the voltage between the gate and drain and the hot-carrier effect of the MOS transistor of the present invention can thus be effectively reduced. In addition, the conductive layer of poly silicon germanium is positioned between the gate oxide layer and the polysilicon conductive layer according to the present invention. As a result, movements of the boron ions from the polysilicon conductive layer to the silicon substrate are prevented, thus improving the electrical performance of the MOS transistor.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method of fabricating a vertical metal-oxide semiconductor (MOS) transistor, the method comprising:
providing a silicon substrate;
forming a gate mask on the silicon substrate;
etching region of the silicon substrate not covered by the gate mask to a predetermined depth;
forming a silicon oxide layer on the region of the silicon substrate not covered by the gate mask;
forming, in order, a poly silicon germanium (Si₁₋ₓGeₓ,x=0.05˜−1.0) layer and a poly silicon layer, respectively, on the a surface of the silicon substrate;
performing a first etching back process to form a first spacer consisting of the poly silicon layer, the poly silicon germanium layer and the silicon oxide layer on the region of the silicon substrate below the gate mask;
removing the gate mask;
performing a selective etching process to remove portions of both the poly silicon germanium layer and the silicon oxide layer;
performing a doping process to form lightly doped drains (LDD) of the vertical MOS transistor; and
performing a first ion implantation process to form a drain and a source of the vertical MOS transistor.

2. The method of claim 1 wherein a method of forming the gate mask comprises:
forming a patterned first sacrificial layer on the surface of the silicon substrate;
forming a second sacrificial layer on the silicon substrate to cover the first sacrificial layer;
performing a second etching back process on the second sacrificial layer to form at least one second spacer consisting of the second sacrificial layer on the side wall of the first sacrificial layer, the second spacer functioning as the gate mask; and
removing the first sacrificial layer.

3. The method of claim 2 wherein the first sacrificial layer comprises silicon oxide compounds, and the second sacrificial layer comprises silicon nitride compounds.

4. The method of claim 1 wherein the doping process comprises a plasma doping process.

5. The method of claim 1 wherein the method further comprises a second ion implantation process to adjust a threshold voltage (Vₜ) of the vertical MOS transistor.

6. A method of fabricating a vertical metal-oxide semiconductor (MOS) transistor, the method comprising:
providing a silicon substrate;
forming a gate mask on the silicon substrate;
etching region of the silicon substrate not covered by the gate mask to a predetermined depth;
forming a silicon oxide layer on the region of the silicon substrate not covered by the gate mask;
forming a first conductive layer and a second conductive layer, respectively, on the a surface of the silicon substrate;
performing a first etching back process to form a first spacer consisting of the second conductive layer, the first conductive layer and the silicon oxide layer on the region of the silicon substrate below the gate mask;
removing the gate mask;
performing a selective etching process to remove portions of both the first conductive layer and the silicon oxide layer;
performing a doping process to form lightly doped drains (LDD) of the vertical MOS transistor; and
performing a first ion implantation process to form a drain and a source of the vertical MOS transistor.

7. The method of claim 6 wherein a method of forming the gate mask comprises:
forming a patterned first sacrificial layer on the surface of the silicon substrate;
forming a second sacrificial layer on the silicon substrate to cover the first sacrificial layer;
performing a second etching back process on the second sacrificial layer to form at least one second spacer consisting of the second sacrificial layer on the side wall of the first sacrificial layer, the second spacer functioning as the gate mask; and
removing the first sacrificial layer.

8. The method of claim 7 wherein the first sacrificial layer comprises silicon oxide compounds, and the second sacrificial layer comprises silicon nitride compounds.

9. The method of claim 6 wherein the doping process comprises a plasma doping process.

10. The method of claim 6 wherein the first conductive layer comprises poly silicon germanium and the second conductive layer comprises doped poly silicon.

11. The method of claim 6 wherein the first conductive layer comprises poly silicon germanium and the second conductive layer comprises undoped poly silicon.

12. The method of claim 6 wherein the first conductive layer comprises amorphous silicon and the second conductive layer comprises poly silicon.

13. The method of claim 6 wherein after the region of the silicon substrate not covered by the gate mask is etched to the predetermined depth, the method further comprises a second ion implantation process to adjust a threshold voltage (Vₜ) of the vertical MOS transistor.
